(19) United States
(12) Patent Application Publication
(10) Pub. No.: US 2023/0315327 A1
(43) Pub. Date: Oct. 5, 2023

(54) SOFTWARE-BASED ENTROPY SOURCE BASED ON DRAM ACCESS LATENCIES

(71) Applicant: VMware, Inc., Palo Alto, CA (US)

(72) Inventors: Alex Markuze, Herzliya (IL); Avishay Yanai, Herzliya (IL); Igor Golikov, Herzliya (IL); John Manferdelli, San Francisco, CA (US); Ittai Abraham, Herzliya (IL)

(21) Appl. No.: 17/710,717

(22) Filed: Mar. 31, 2022

(51) Int. Cl. G06F 3/06

(52) U.S. Cl. CPC G06F 3/0653; G06F 3/0673; G06F 3/0604

(57) ABSTRACT

In one set of embodiments, a computer system can initiate a memory stress test on a memory subsystem of the computer system, where the memory subsystem including a dynamic random access memory (DRAM). Then, while the memory stress test is running, the computer system can execute a plurality of access operations for accessing the DRAM, measure the time taken to complete each access operation, combine the measured times to compute a value, and output the value as an entropy sample.

### CROSS-REFERENCES TO RELATED APPLICATIONS

The present application is related to U.S. patent application Ser. No. ______ (Attorney Docket No. 1120 (86-040400)), entitled “Software-Based Entropy Source Based on Rowhammer DRAM Vulnerability,” and U.S. patent application Ser. No. ______ (Attorney Docket No. 1122 (86-040600)), entitled “Software-Based Entropy Source Based on Race Conditions,” both of which are filed concurrently herewith. The entire contents of these related applications are incorporated herein by reference for all purposes.

### BACKGROUND

Unless otherwise indicated, the subject matter described in this section is not prior art to the claims of the present application and is not admitted as being prior art by inclusion in this section.

In information theory, entropy is a measure of the unpredictability of data. For example, consider a system that samples data instances x₁, x₂ . . . from a sample space {s₁, . . . , sₙ} according to a probability distribution P(s₁), . . . , P(sₙ) where P(sᵢ) is the likelihood of sampling sᵢ for a given xⱼ. In this scenario, the entropy property of the system measures the uncertainty (or unpredictability) of the sampling outcomes, or in other words the uncertainty/unpredictability of the values of sampled data instances x₁, x₂ . . . . The more unpredictable x₁, x₂ . . . are, the higher the entropy. If x₁, x₂ . . . can be predicted with perfect accuracy, the entropy is zero. According to a formal definition referred to as Shannon's entropy (i.e., H_{Shannon}), the entropy of this system is computed as H_{Shannon}(P(s₁), . . . , P(sₙ))=Σᵢ₌₁ⁿP(sᵢ)·log₂ P(sᵢ).

Random number generators (RNGs) rely on an entropy source (i.e., an entity that exhibits some level of entropy) to obtain unpredictable data, which the RNGs then use to produce their random outputs. RNGs employed for cryptography or other security-oriented tasks generally rely on hardware-based entropy sources, such as special circuitry implemented in certain central processing units (CPUs), that derive their entropy from observations/measurements of physical phenomena (e.g., electromagnetic fields, radioactive decay, metastable circuit states, voltage variation in noisy diodes, etc.). These physical phenomena expose probability distributions pertaining to their states that are highly entropic in nature and are largely immune from adversarial influence and attacks.

However, hardware-based entropy sources are not available or practical in all settings. For example, Internet of Things (IoT) devices are often constrained to using lower-end CPUs that do not include any special entropy source circuitry in order to meet specific cost, power, and/or thermal requirements. As another example, virtualization solutions (e.g., hypervisors) that emulate physical hardware for consumers (e.g., virtual machines) should be able to obtain entropy without direct access to such circuitry, regardless of whether the circuitry is present or not in hardware.

### BRIEF DESCRIPTION OF THE DRAWINGS

FIG. 1 depicts an example computer system.

FIG. 2 depicts a workflow for implementing a software-based entropy source based on race conditions according to certain embodiments.

FIGS. 3 and 4 depicts histograms of entropy samples that may be generated by the software-based entropy source of FIG. 2 according to certain embodiments.

FIG. 5 depicts a workflow for implementing a software-based entropy source based on the Rowhammer DRAM vulnerability according to certain embodiments.

FIG. 6 depicts a workflow for implementing a software-based entropy source based on DRAM access latencies according to certain embodiments.

### DETAILED DESCRIPTION

In the following description, for purposes of explanation, numerous examples and details are set forth in order to provide an understanding of various embodiments. It will be evident, however, to one skilled in the art that certain embodiments can be practiced without some of these details or can be practiced with modifications or equivalents thereof.

### 1. Overview

Embodiments of the present disclosure are directed to novel software-based entropy sources that can be used for random number generation and other similar applications. A software-based entropy source is an entity that generates unpredictable data via entropy that is derived from software processes. This type of entropy (sometimes referred to as computational entropy) still relies to an extent on physical phenomena, but the root causes of those physical phenomena are created/governed by software.

In certain embodiments, the novel software-based entropy sources include a source based on software race conditions, a source based on the Rowhammer dynamic random access memory (DRAM) vulnerability, and a source based on DRAM access latencies. As discussed in further detail below, these software-based entropy sources are relatively straightforward to implement while offering a level of unpredictability and robustness against adversarial influence/attacks that is comparable to hardware-based entropy sources.

### 2. Example Computer System

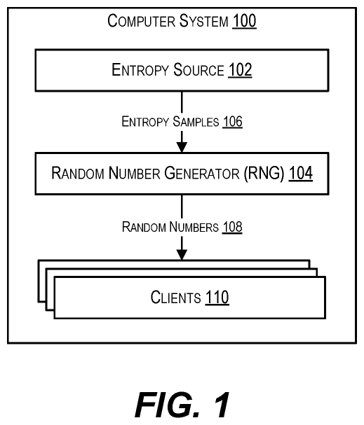

FIG. 1 depicts an example computer system 100 in which embodiments of the present disclosure may be implemented. Computer system 100 includes, among other things, an entropy source 102 that is communicatively coupled with a random number generator (RNG) 104. Generally speaking, entropy source 102 is an entity that exhibits entropy derived from an underlying process or phenomenon and outputs unpredictable data (shown as entropy samples 106) in accordance with that entropy. For example, entropy samples 106 can comprise a stream of nondeterministic random bits, bytes, or the like.

RNG 104 receives the entropy samples output by entropy source 102 (thereby “obtaining entropy” from source 102) and uses the samples to generate a sequence of random numbers 108 over a defined interval (e.g., [0,1]). Ideally, random numbers 108 are statistically independent (such that a particular number is not more or less likely to follow another number), selected from the interval via a uniform probability distribution (such that none of the numbers are more “popular” or appear more often in the RNG output than others), and are unpredictable. These random numbers are then consumed by one or more clients 110 of RNG 104 for various purposes (e.g., cryptography, simulation, gaming, etc.).

According to one approach, RNG 104 can generate random numbers 108 by applying one or more functions (e.g., a sampling function, a transformation function, etc.) to entropy samples 106 received from entropy source 102. According to another approach, RNG 104 can generate random numbers 108 by providing entropy samples 106 as seed value inputs to a pseudorandom number generator (PRNG) (not shown), which can effectively “spread” each entropy sample into a large set of random values via a deterministic algorithm. With this latter approach, the output of RNG 104 will technically be pseudorandom numbers rather than truly random numbers, which means that the numbers appear random (e.g., exhibit statistical independence and uniform distribution) but are wholly determined by the seed value(s) used to initialize the PRNG. Accordingly, these pseudorandom numbers can be replicated (and thus are predictable) if the original seed values are known.

As noted in the Background section, RNGs that are used for tasks where security is important typically rely on a hardware-based entropy source, or in other words an entropy source which outputs unpredictable data based on the direct observation/measurement of physical phenomena such as electromagnetic fields, radioactive decay, thermal noise, back body radiation, Johnson noise, quantum transitions, and so on. One example of a hardware-based entropy source is the special entropy source circuitry implemented in certain Intel and AMD CPUs. In the case of Intel CPUs, this circuitry measures thermal noise within the CPU silicon and outputs a random stream of bits based on samplings of those measurements. Hardware-based entropy sources are desirable in security-oriented contexts because their underlying physical phenomena expose probability distributions for their states that are well-studied (implying uncertainty about the outcome when sampling that state) and the theories behind the physical phenomena provide convincing evidence that an adversary would not be able to influence or change their probability distributions to his/her benefit.

However, relying solely on hardware-based sources of entropy like the special CPU circuitry mentioned above is problematic for several reasons. First, a hardware-based entropy source can become temporarily inoperable due to issues such as “stuck bits” and unexpected electromagnetic emissions, or in the worst case can experience an outright failure. The former can lead to long delays in providing new entropy samples to a consumer such as RNG 104 and the latter can lead to a breakdown in system integrity due to the inability to carry out key functions.

Second, some computing platforms such as virtualized platforms may not have access to any hardware-based entropy sources at all. This means that the security functions of such platforms which rely on robust random number generation (e.g., cryptographic functions) are vulnerable to compromise/attack, absent another source of entropy.

Third, hardware-based entropy sources are relatively expensive to implement, both in terms of bill of materials (BOM) cost and the space they consume on a physical CPU die. This makes hardware-based entropy sources impractical for inclusion in lower-end computing devices such as IoT devices and the like.

To address the foregoing and other related problems, the remaining sections of this disclosure describe various techniques for implementing a software-based, rather than hardware-based, version of entropy source 102 of FIG. 1. For example, section (3) below details techniques for implementing a software-based entropy source based on race conditions in a multiprocessor system (i.e., a computer system comprising multiple physical processing cores). Such race conditions can arise when a resource is read or written by multiple competitive software processes running concurrently across the processing cores, resulting in uncertainty/entropy in system output.

Section (4) below details techniques for implementing a software-based entropy source based on a security vulnerability in DRAM devices known as “Rowhammer.” A Rowhammer attack exploits an electromagnetic phenomenon present in several generations of DRAM that can cause the cells of certain DRAM rows to flip their states (i.e., change from 0 to 1 or vice versa) without explicit accesses to those memory addresses. This bit-flipping is unpredictable in nature and thus can be leveraged to obtain entropy.

And section (5) below details techniques for implementing a software-based entropy source based on DRAM access latencies. Such access latencies can vary randomly over time due to a number of physical and non-physical factors and thus can also be leveraged to obtain entropy.

With these novel software-based entropy sources, high-quality entropy can be achieved for random number generation and/or other applications in a relatively easy-to-implement manner. On computing platforms that have access to existing hardware-based entropy sources, these software-based sources can be used in conjunction with the hardware-based sources to increase the reliability and robustness of entropy sample generation. On computing platforms that do not have access to a hardware-based entropy source, these software-based sources can act as good sources of entropy on their own (either individually or in combination), thereby resulting in increased security and capabilities for those platforms.

It should be appreciated that FIG. 1 and the foregoing description of computer system 100 are illustrative and not intended to limit embodiments of the present disclosure. For example, the various entities shown in computer system 100 (e.g., entropy source 102, RNG 104, and client 110) may be organized according to different arrangements/configurations or may include subcomponents or functions that are not specifically described. One of ordinary skill in the art will recognize other variations, modifications, and alternatives.

### 3. Software-Based Entropy Source Based on Race Conditions

A race condition is a scenario in which the output of a software system changes depending on the order in which certain events occur or are executed. For example, imagine a shared global counter ctr that is unprotected by a semaphore or lock. Assume ctr is initialized to 1 and two concurrently-running software processes are programmed to read the counter and increment it. Then consider the following possible sequences of events:
1. Option 1: The first process reads ctr and stores ctr=ctr+1. The second process subsequently reads ctr and stores ctr=ctr+1.
2. Option 2: Both processes read ctr and then both processes store ctr=ctr+1.

At the end of the sequence of option 1, ctr will equal 3 because the first process will increment it from 1 to 2 and the second process will increment it from 2 to 3. However, at the end of the sequence of option 2, ctr will equal 2 because both processes will read the initial value of ctr as 1 and then increment ctr from 1 to 2. These two possible outcomes imply that ctr is a random variable whose value is subject to a probability distribution and thus ctr exhibits some level of entropy. For example, if the sequences of options 1 and 2 are equally likely to occur, the probability that final value of ctr=3 is 0.5, the probability that final value of ctr=2 is also 0.5, and the Shannon entropy of ctr is 2·log 2 (0.5)=1.

The particular value that random variable ctr ultimately takes (and thus, the particular sequence of events that are ultimately executed) can depend on a large number of factors. For example, these factors can include which physical processing cores (or hardware threads) the first and second processes are placed on, the specific times at which the processes begin execution, and timing skews between the processes. The factors can also include variations in execution times (i.e., execution jitter) of certain instructions on each processing core/hardware thread, external events (e.g., periodic timer interrupts, random network packet processing, etc.), data residency in CPU caches, frequency of cache flushes, inter-process communication (IPC) calls, DRAM access times, the state of all running processes and their effects on software scheduling, and more. Taken together, all of these factors suggest that it is computationally infeasible for an adversary to predict the results of a race condition with any level of accuracy beyond random guessing.

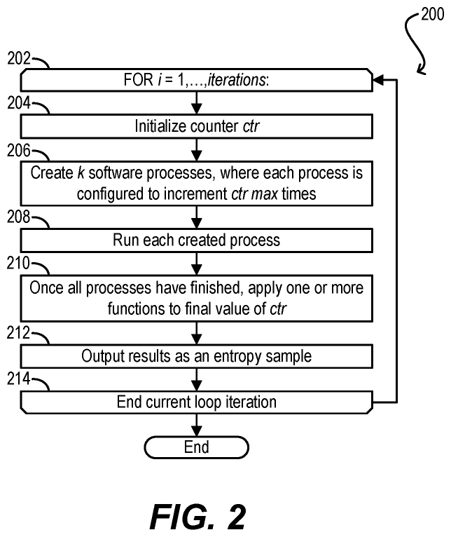

With the foregoing in mind, FIG. 2 depicts a workflow 200 that can be executed by a computer system such as system 100 of FIG. 1 for implementing a software-based entropy source that derives its entropy from a race condition according to certain embodiments. At a high level, workflow 200 establishes a race condition among k concurrently running software processes (where each process runs on a separate physical processing core or hardware thread) and generates entropy samples based on the unpredictable output of that race condition. In the specific example of workflow 200, each process is programmed to increment a shared global counter ctr (without any synchronization mechanism such as a semaphore or lock) max times. For example, if max=2²¹, each process will independently increment ctr 2²¹ times. In this scenario the unpredictability of the race condition output, which is the final value of ctr, depends upon the order in which the k processes execute their increment operations. In other embodiments, other types of race conditions may be employed.

Starting with block 202, the computer system can enter a loop for variable i=1, . . . , iterations, where iterations is a constant indicating the number of times to repeat the workflow. Within this loop, the computer system can initialize counter ctr to some initial value (e.g., 0) (block 204).

The computer system can then create the k software processes (block 206) and kick off (i.e., run) each created process (block 208). As mentioned previously, each process can be configured to execute program code for incrementing counter ctr max times.

Once all processes have finished their execution, the computer system can apply one or more functions to the final value of ctr (block 210) and output the result as an entropy sample (block 212). For example, in one set of embodiments the one or more functions can include sampling the least significant byte (LSB) of the counter.

The computer system can then reach the end of the current loop iteration (block 214) and return to the top of the loop to carry out the next iteration i. Upon completing all iterations, the workflow can end.

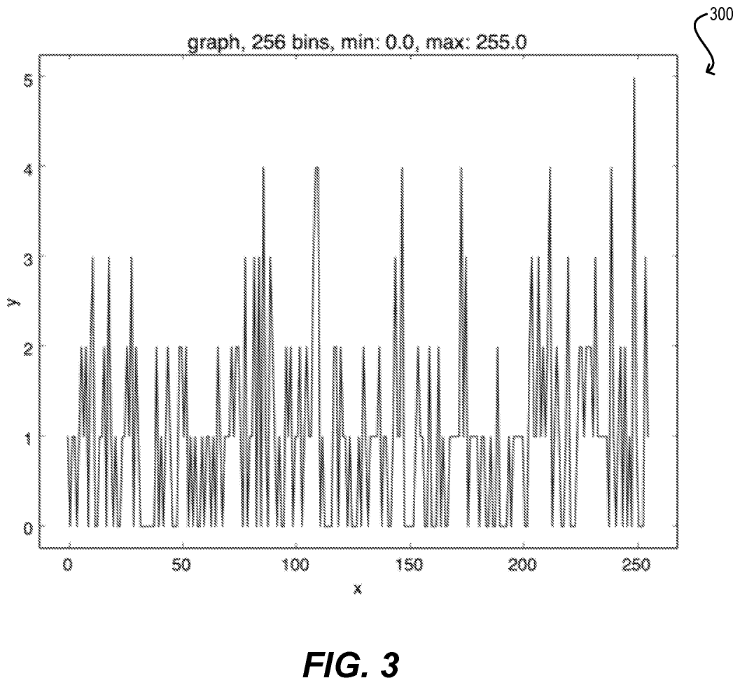

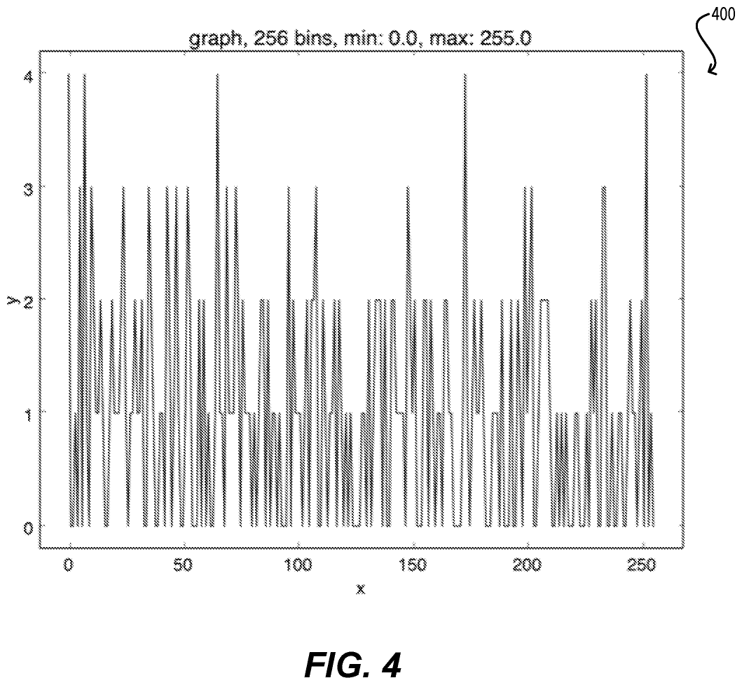

For illustration purposes, FIG. 3 depicts a representative histogram 300 of the entropy samples generated by a software-based entropy source implemented via workflow 200 in a scenario where max=2²¹ and k=2, and FIG. 4 depicts a representative histogram 400 of the entropy samples generated by that software-based entropy source in a scenario where max=2²¹ and k=8. In these histograms, the x-axis represents the value of the LSB of counter ctr and the y-axis represents the number of times that value was output by the source.

As can be seen, the entropy (namely, variance in LSB values) obtained in the scenario of FIG. 4 (corresponding to eight processes) is higher than the entropy obtained in the scenario of FIG. 3 (corresponding to only two processes). This is expected as there are a greater number of possible execution sequences, and thus greater unpredictability regarding the final value of the counter, with larger numbers of concurrent processes. The Shannon entropy of the scenario of FIG. 4 is approximately 7, which is fairly high and indicates that the resulting entropy samples are unpredictable.

One potential contributor to the lower entropy obtained in the scenario of FIG. 4 involving only two processes is that one process may occasionally finish its incrementing of counter ctr before there is a context switch and the other process can begin its execution. This is particularly likely if both processes run as separate hardware threads on a single processing core via symmetric multi-threading (SMT) because the counter will be brought into that core's first-level CPU cache and remain there, allowing the first process to access and update it very quickly without performing roundtrips to system memory (i.e., DRAM).

In these types of scenarios, it is possible to increase the entropy of the final value of ctr by having each process sleep for some amount of time between its increment operations and/or by flushing the CPU caches on a periodic basis. This will effectively “slow down” each process, resulting in more context switches and greater variability in the event sequences that occur.

### 4. Software-Based Entropy Source Based on Rowhammer DRAM Vulnerability

In DRAM, each bit of stored data is held in a memory cell that is implemented via a capacitor and a transistor. The charge state of a cell's capacitor determines whether that cell holds a value of 0 or 1. A group of contiguous cells are organized into a row, which is typically 512 bytes in size. Multiple rows are organized into matrices (also known as arrays).

Rowhammer is a bug/vulnerability present in certain generations of DRAM (including modern versions available today) that arises from the tendency of DRAM cells to interact electrically with each other via leaking charges. In a typical Rowhammer attack, an attacker carries out specially crafted memory access patterns with respect to one or more target rows. If the attack is successful, the memory accesses directed to the target DRAM row(s) lead to random bit flips in the cells of neighboring rows that were not explicitly accessed/addressed, due to the leakage of charges into those neighboring rows. This in turn can allow the attacker to, e.g., gain access to physical memory outside of the scope of the attacker's original execution context and/or implement other types of exploits. It is possible to mitigate this bit flipping phenomenon by enabling the error correcting code (ECC) functionality found in ECC DRAM. However, the efficiency of ECC against Rowhammer is not absolute.

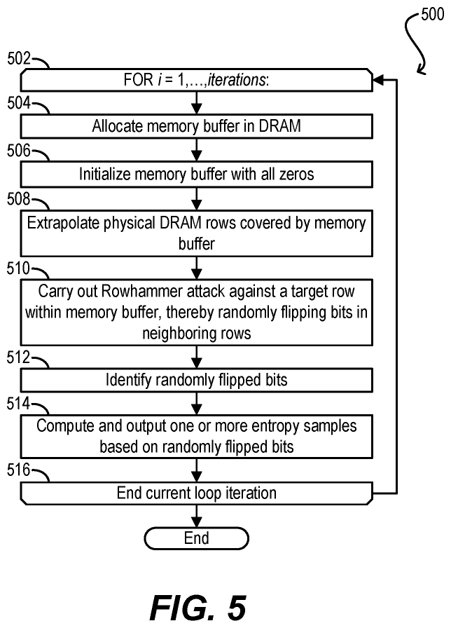

Because the bit flips induced by a Rowhammer attack are random in nature, Rowhammer can be leveraged to obtain entropy on computer systems that are susceptible to this vulnerability. Accordingly, FIG. 5 depicts a workflow 500 that can be executed by such a computer system for implementing a software-based entropy source that derives its entropy from Rowhammer bit flips according to certain embodiments. It is assumed that workflow 500 is executed upon system boot and before ECC is enabled on the system's DRAM modules (if supported). This improves the efficiency of the process and avoids unintended bit flips in physical memory regions containing data needed by other processes.

Starting with block 502, the computer system can enter a loop for variable i=1, . . . , iterations, where iterations is a constant indicating the number of times to repeat the workflow. Within this loop, the computer system can allocate a memory buffer in DRAM (block 504) and initialize the memory buffer with all zeros (block 506).

At block 508, the computer system can extrapolate the physical DRAM rows covered by the memory buffer. This generally requires knowledge of the physical memory addresses that the memory buffer is mapped to and converting those physical memory addresses to row identifiers.

Upon extrapolating the rows, the computer system can carry out a Rowhammer attack targeting a single, specific target row within the memory buffer, which yields randomly flipped bits (i.e., from 0 to 1) in neighboring rows around that target row (block 510).

The computer system can then identify the randomly flipped bits (block 512) and can use that information to compute and output one or more entropy samples for consumption by a downstream entity (e.g., RNG 104 of FIG. 1) (block 514). In one set of embodiments, the entropy sample computation at block 514 can involve computing the total number/count of bits that have been flipped. In other embodiments other types of techniques may be employed, such as computing an integer value representing the data contents of the memory buffer (excluding the row that is targeted). One of ordinary skill in the art will recognize other possible variations and alternatives.

Finally, at block 516, the computer system can reach the end of the current loop iteration and return to the top of the loop to carry out the next iteration i. Upon completing all iterations, the workflow can end.

It should be noted that one significant advantage of this Rowhammer-derived entropy source is that it can be effectively used on lower-end computing devices that may not have multiple physical processing cores (or only a few at best). This is in contrast to the race condition-derived entropy source discussed in section (3) above, which is better suited to computer systems that have a reasonable number of physical processing cores in order to generate high-quality entropy samples. Lower-end computing devices are also more likely use DRAM modules that are susceptible to Rowhammer (e.g., non-ECC modules).

### 4. Software-Based Entropy Source Based on DRAM Access Latencies

Apart from Rowhammer, it is also possible to leverage DRAM access latencies (also referred to as access times) to create a software-based entropy source. It is known that the time needed to read or write data in DRAM can vary in an unpredictable way depending on various physical and non-physical factors. These factors can include physical attributes of the DRAM, physical attributes of the memory subsystem (e.g., controller, bus, etc.), software attributes of the operating system, the nature of the data being accessed (e.g., size, type, etc.), the specific process performing the memory access, and so on. Further, it is known that such access latency variations can become even more pronounced/unpredictable in scenarios where the memory subsystem is under high stress.

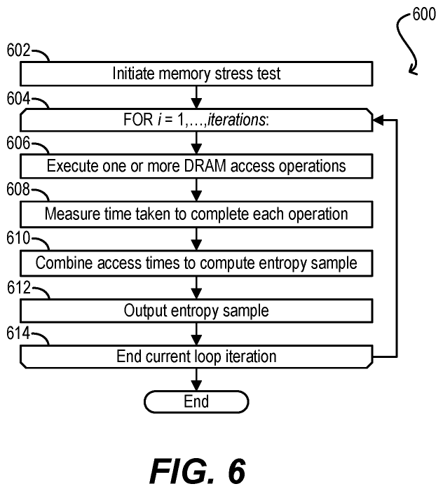

Accordingly, FIG. 6 depicts a workflow 600 that can be executed by a computer system like system 100 of FIG. 1 for implementing a software-based entropy source that derives its entropy from varying DRAM access latencies according to certain embodiments. Starting with block 602, the computer system can initiate a memory stress test utility or benchmark on all of the processing cores of the system in order to artificially stress the system's memory subsystem (which includes the system's DRAM modules). In various embodiments, this memory stress test utility or benchmark can induce or result in high memory bandwidth usage to/from DRAM.

While the stress test utility/benchmark is running, the computer system can enter a loop for variable i=1, . . . , iterations (block 604). Within this loop, the computer system can execute one or more DRAM access (e.g., read or write) operations (block 606) and measure the time it takes to complete each operation (block 608). For example, the computer system can measure the number of CPU clock cycles required for each operation.

Upon measuring the access times, the computer system can combine the access times in some manner to compute an entropy sample (block 610) and can output the entropy sample for consumption by a downstream entity (e.g., RNG 104 of FIG. 1) (block 612). The combining at block 610 can take multiple forms; one example is taking the least or most significant bit of each of eight measured access times to create a random byte. Another example is computing an exclusive OR (XOR) of bitstring representations of the measured access times.

Finally, at block 614, the computer system can reach the end of the current loop iteration and return to the top of the loop to carry out the next iteration i. Upon completing all iterations, the workflow can end.

Because this access latency-derived entropy source is strongly reliant on the physical characteristics of DRAM hardware, it can be considered more theoretically secure (in terms of resilience against adversarial influence and attacks) than the race condition and Rowhammer-derived entropy sources described above. Thus, it may be useful to implement this source in conjunction with (or in lieu of) the other two types of software-based sources in environments where hardware-based entropy sources are unavailable but where security is of paramount importance.

Certain embodiments described herein can employ various computer-implemented operations involving data stored in computer systems. For example, these operations can require physical manipulation of physical quantities—usually, though not necessarily, these quantities take the form of electrical or magnetic signals, where they (or representations of them) are capable of being stored, transferred, combined, compared, or otherwise manipulated. Such manipulations are often referred to in terms such as producing, identifying, determining, comparing, etc. Any operations described herein that form part of one or more embodiments can be useful machine operations.

Further, one or more embodiments can relate to a device or an apparatus for performing the foregoing operations. The apparatus can be specially constructed for specific required purposes, or it can be a generic computer system comprising one or more general purpose processors (e.g., Intel or AMD x86 processors) selectively activated or configured by program code stored in the computer system. In particular, various generic computer systems may be used with computer programs written in accordance with the teachings herein, or it may be more convenient to construct a more specialized apparatus to perform the required operations. The various embodiments described herein can be practiced with other computer system configurations including handheld devices, microprocessor systems, microprocessor-based or programmable consumer electronics, minicomputers, mainframe computers, and the like.

Yet further, one or more embodiments can be implemented as one or more computer programs or as one or more computer program modules embodied in one or more non-transitory computer readable storage media. The term non-transitory computer readable storage medium refers to any storage device, based on any existing or subsequently developed technology, that can store data and/or computer programs in a non-transitory state for access by a computer system. Examples of non-transitory computer readable media include a hard drive, network attached storage (NAS), read-only memory, random-access memory, flash-based nonvolatile memory (e.g., a flash memory card or a solid state disk), persistent memory, NVMe device, a CD (Compact Disc) (e.g., CD-ROM, CD-R, CD-RW, etc.), a DVD (Digital Versatile Disc), a magnetic tape, and other optical and non-optical data storage devices. The non-transitory computer readable media can also be distributed over a network coupled computer system so that the computer readable code is stored and executed in a distributed fashion.

Finally, boundaries between various components, operations, and data stores are somewhat arbitrary, and particular operations are illustrated in the context of specific illustrative configurations. Other allocations of functionality are envisioned and may fall within the scope of the invention(s). In general, structures and functionality presented as separate components in exemplary configurations can be implemented as a combined structure or component. Similarly, structures and functionality presented as a single component can be implemented as separate components.

As used in the description herein and throughout the claims that follow, “a,” “an,” and “the” includes plural references unless the context clearly dictates otherwise. Also, as used in the description herein and throughout the claims that follow, the meaning of “in” includes “in” and “on” unless the context clearly dictates otherwise.

The above description illustrates various embodiments along with examples of how aspects of particular embodiments may be implemented. These examples and embodiments should not be deemed to be the only embodiments and are presented to illustrate the flexibility and advantages of particular embodiments as defined by the following claims. Other arrangements, embodiments, implementations, and equivalents can be employed without departing from the scope hereof as defined by the claims.

What is claimed is:

1. A method comprising:
initiating, by a computer system, a memory stress test on a memory subsystem of the computer system, the memory subsystem including a dynamic random access memory (DRAM); and
while the memory stress test is running:
executing, by the computer system, a plurality of access operations for accessing the DRAM;
measuring, by the computer system, a time taken to complete each access operation;
combining, by the computer system, the measured times to compute a value; and
outputting the value.

2. The method of claim 1 wherein the memory stress test causes high memory bandwidth usage in the memory subsystem that in turn increases variability of DRAM access times.

3. The method of claim 1 wherein the measuring comprises measuring a number of central processing unit (CPU) clock cycles needed to complete said each access operation.

4. The method of claim 1 wherein the combining comprises:
extracting a least or most significant bit of eight measured times; and
using the extracted bits to create a random byte value.

5. The method of claim 1 wherein the combining comprises computing an exclusive OR of bitstring representations of the measured times.

6. The method of claim 1 wherein the value is an entropy sample that is provided to a random number generator for generating one or more random numbers.

7. The method of claim 6 wherein the random number generator uses the entropy sample as a seed value for initializing a pseudorandom number generator.

8. A non-transitory computer readable storage medium having stored thereon program code executable by a computer system, the program code embodying a method comprising:
initiating a memory stress test on a memory subsystem of the computer system, the memory subsystem including a dynamic random access memory (DRAM); and
while the memory stress test is running:
executing a plurality of access operations for accessing the DRAM;
measuring a time taken to complete each access operation;
combining the measured times to compute a value; and
outputting the value.

9. The non-transitory computer readable storage medium of claim 8 wherein the memory stress test causes high memory bandwidth usage in the memory subsystem that in turn increases variability of DRAM access times.

10. The non-transitory computer readable storage medium of claim 8 wherein the measuring comprises measuring a number of central processing unit (CPU) clock cycles needed to complete said each access operation.

11. The non-transitory computer readable storage medium of claim 8 wherein the combining comprises:
extracting a least or most significant bit of eight measured times; and
using the extracted bits to create a random byte value.

12. The non-transitory computer readable storage medium of claim 8 wherein the combining comprises computing an exclusive OR of bitstring representations of the measured times.

13. The non-transitory computer readable storage medium of claim 8 wherein the value is an entropy sample that is provided to a random number generator for generating one or more random numbers.

14. The non-transitory computer readable storage medium of claim 13 wherein the random number generator uses the entropy sample as a seed value for initializing a pseudorandom number generator.

15. A computer system comprising:
a processor;
a memory subsystem including a dynamic random access memory (DRAM); and
a non-transitory computer readable medium having stored thereon program code that, when executed, causes the processor to:
initiate a memory stress test on the memory subsystem; and
while the memory stress test is running:
execute a plurality of access operations for accessing the DRAM;
measure a time taken to complete each access operation;
combine the measured times to compute a value; and
output the value.

16. The computer system of claim 15 wherein the memory stress test causes high memory bandwidth usage in the memory subsystem that in turn increases variability of DRAM access times.

17. The computer system of claim 15 wherein the program code that causes the processor to measure the time needed to complete each access operation comprises program code that causes the processor to measure a number of central processing unit (CPU) clock cycles needed to complete said each access operation.

18. The computer system of claim 15 wherein the program code that causes the processor to combine the measured times comprises program code that causes the processor to:
extract a least or most significant bit of eight measured times; and
use the extracted bits to create a random byte value.

19. The computer system of claim 15 wherein the program code that causes the processor to combine the measured times comprises program code that causes the processor to compute an exclusive OR of bitstring representations of the measured times.

20. The computer system of claim 15 wherein the value is an entropy sample that is provided to a random number generator for generating one or more random numbers.

21. The computer system of claim 20 wherein the random number generator uses the entropy sample as a seed value for initializing a pseudorandom number generator.
